(19) United States
(12) Patent Application Publication
(10) Pub. No.: US 2023/0045374 A1
(43) Pub. Date: Feb. 9, 2023

(54) ACOUSTIC WAVE DEVICE

(71) Applicant: Murata Manufacturing Co., Ltd., Nagaokakyo-shi (JP)

(72) Inventors: Koji YAMAMOTO, Nagaokakyo-shi (JP); Katsuya DAIMON, Nagaokakyo-shi (JP)

(21) Appl. No.: 17/972,605

(22) Filed: Oct. 25, 2022

Related U.S. Application Data
(63) Continuation of application No. PCT/JP2021/018965, filed on May 19, 2021.

(30) Foreign Application Priority Data
May 28, 2020 (JP) 2020-093432

(51) Int. Cl. H03H 9/13; H03H 9/02

(52) U.S. Cl. CPC H03H 9/131; H03H 9/02992; H03H 9/02842; H03H 9/02007

(57) ABSTRACT

An acoustic wave device includes an intermediate layer and a piezoelectric film that are laminated in that order on the support substrate. An interdigital transducer (IDT) electrode is provided on the piezoelectric film. Cavities are provided at least one of a location between the support substrate and the intermediate layer and a location in the intermediate layer.

### CROSS REFERENCE TO RELATED APPLICATIONS

This application claims the benefit of priority to Japanese Patent Application No. 2020-093432, filed on May 28, 2020, and is a Continuation Application of PCT Application No. PCT/JP2021/018965, filed on May 19, 2021. The entire contents of each application are hereby incorporated herein by reference.

### BACKGROUND OF THE INVENTION

### 1. Field of the Invention

The present invention relates to an acoustic wave device including a support substrate, an intermediate layer, and a piezoelectric film that are laminated together.

### 2. Description of the Related Art

Various types of acoustic wave devices in which an intermediate layer is provided between a support substrate and a piezoelectric film have been proposed. International Publication No. 2012/086639 describes an acoustic wave device in which a high-acoustic-velocity film, a low-acoustic-velocity film, and a piezoelectric film are laminated in that order on a support substrate. An IDT electrode is provided on the piezoelectric film.

In the acoustic wave device described in International Publication No. 2012/086639, a wave that travels from the piezoelectric film toward the support substrate is reflected by the support substrate, and a response in a higher-order mode tends to occur. Therefore, when the acoustic wave device is used as a band pass filter, a spurious response outside a pass band may occur. As a result, there is a risk of degradation of filter characteristics.

### SUMMARY OF THE INVENTION

Preferred embodiments of the present invention provide acoustic wave devices in each of which degradation of characteristics due to a higher-order mode does not easily occur.

An acoustic wave device according to a preferred embodiment of the present invention includes a support substrate, an intermediate layer provided on the support substrate, a piezoelectric film laminated on the intermediate layer, and an interdigital transducer (IDT) electrode provided on the piezoelectric film. A plurality of cavities are provided at at least one of a location between the support substrate and the intermediate layer and a location in the intermediate layer. The plurality of cavities overlap the IDT electrode in plan view.

Preferred embodiments of the present invention provide acoustic wave devices in each of which degradation of characteristics due to a higher-order mode does not easily occur.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is a front sectional view of an acoustic wave device according to a first preferred embodiment of the present invention, and FIG. 1B is a schematic plan view illustrating an electrode structure of the acoustic wave device.

FIG. 2 is an enlarged partial sectional view illustrating a main portion of the acoustic wave device according to the first preferred embodiment of the present invention.

FIG. 3 is an enlarged partial front sectional view illustrating cavities in a first modification of an acoustic wave device according to the first preferred embodiment of the present invention.

FIG. 4 is an enlarged partial front sectional view illustrating cavities in a second modification of an acoustic wave device according to the first preferred embodiment of the present invention.

FIG. 5 is an enlarged partial front sectional view illustrating cavities in a third modification of an acoustic wave device according to the first preferred embodiment of the present invention.

FIG. 6 is a front sectional view of an acoustic wave device according to a second preferred embodiment of the present invention.

FIG. 7 is an enlarged partial front sectional view illustrating a main portion of an acoustic wave device according to a third preferred embodiment of the present invention.

FIG. 8 is an enlarged partial front sectional view illustrating a main portion of an acoustic wave device according to a fourth preferred embodiment of the present invention.

FIG. 9 is a front sectional view of an acoustic wave device according to a fifth preferred embodiment of the present invention.

### DETAILED DESCRIPTION OF THE PREFERRED EMBODIMENTS

Preferred embodiments of the present invention will be described with reference to the drawings to clarify the present invention.

Preferred embodiments described in this specification are illustrative and it is possible to partially replace or combine the structures in different preferred embodiments.

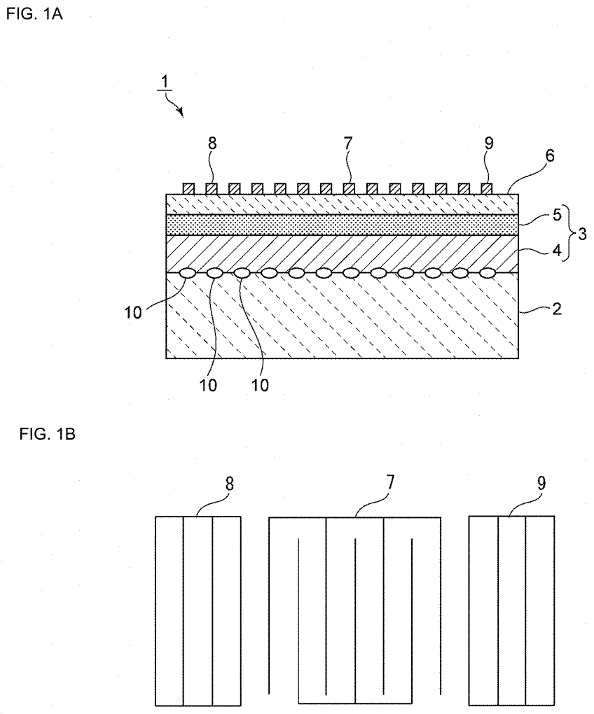

FIG. 1A is a front sectional view of an acoustic wave device according to a first preferred embodiment of the present invention, and FIG. 1B is a schematic plan view illustrating an electrode structure of the acoustic wave device.

An acoustic wave device 1 includes a support substrate 2. An intermediate layer 3 and a piezoelectric film 6 are preferably laminated in that order on the support substrate 2. The intermediate layer 3 includes a high-acoustic-velocity film 4 laminated on the support substrate 2 and a low-acoustic-velocity film 5 provided between the high-acoustic-velocity film 4 and the piezoelectric film 6.

An IDT electrode 7 and reflectors 8 and 9 are provided on the piezoelectric film 6. As illustrated in FIG. 1B, the reflectors 8 and 9 are provided on two sides of the IDT electrode 7 in a direction in which an acoustic wave propagates. Thus, an acoustic wave resonator is defined.

The support substrate 2 is preferably made of silicon, for example. The support substrate 2 may alternatively be made of various insulating materials and semiconductor materials. Such a material may be at least one material selected from a group including, for example, silicon, aluminum nitride, aluminum oxide, silicon carbide, silicon nitride, sapphire, lithium tantalate, lithium niobate, quartz crystal, alumina, zirconia, cordierite, mullite, steatite, forsterite, magnesia, and diamond.

The piezoelectric film 6 is preferably made of, for example, a lithium tantalate film, more specifically a LiTaO₃ film in this example. The piezoelectric film 6 may alternatively be made of other piezoelectric materials, such as lithium niobate (LiNbO₃), for example.

The high-acoustic-velocity film 4 is made of a high-acoustic-velocity material. The high-acoustic-velocity material is a material through which a bulk wave propagates at an acoustic velocity higher than an acoustic velocity at which an acoustic wave propagates through the piezoelectric film 6. Examples of the high-acoustic-velocity material include various materials such as aluminum oxide, silicon carbide, silicon nitride, silicon oxynitride, silicon, sapphire, lithium tantalate, lithium niobate, quartz crystal, alumina, zirconia, cordierite, mullite, steatite, forsterite, magnesia, a diamond-like carbon (DLC) film, diamond, a medium having the above-mentioned materials as a main component, and a medium having a mixture of the above-described materials as a main component.

The low-acoustic-velocity film 5 is made of a low-acoustic-velocity material. The low-acoustic-velocity material is a material through which a bulk wave propagates at an acoustic velocity lower than an acoustic velocity at which a bulk wave propagates through the piezoelectric film 6. Examples of the low-acoustic-velocity material include various materials such as silicon oxide, glass, silicon oxynitride, tantalum oxide, a compound obtained by adding fluorine, carbon, boron, hydrogen, or a silanol group to silicon oxide, and a medium having the above-described materials as a main component.

In the present preferred embodiment, the high-acoustic-velocity film 4 is preferably made of, for example, silicon nitride, and the low-acoustic-velocity film 5 is preferably made of, for example, silicon oxide.

The IDT electrode 7 and the reflectors 8 and 9 may be made of various metals, such as, for example, Al, Cu, Au, W, and Mo, or alloys mainly including these metals. The IDT electrode 7 and the reflectors 8 and 9 may be defined by a multilayer body including a plurality of metal films.

The acoustic wave device 1 includes a plurality of cavities 10 provided between the support substrate 2 and the intermediate layer 3, and more specifically, between the support substrate 2 and the high-acoustic-velocity film 4 (at an interface between the support substrate 2 and the high-acoustic-velocity film 4). When the cavities are provided at the interface, in regions where the cavities are provided, the support substrate 2 and the high-acoustic-velocity film 4 have the cavities therebetween, and therefore no interface is present between the support substrate 2 and the high-acoustic-velocity film 4.

In the acoustic wave device 1, an alternating current voltage is applied to the IDT electrode 7 to excite an acoustic wave. The intermediate layer 3 defined by the high-acoustic-velocity film 4 and the low-acoustic-velocity film 5 is between the support substrate 2 and the piezoelectric film 6. Therefore, the acoustic wave is confined in the piezoelectric film 6. Accordingly, good resonance characteristics can be obtained.

When the IDT electrode 7 is excited, a wave in a mode other than a main mode that is used is also excited. The wave in the mode other than the main mode also propagates in a depth direction, that is, in a direction from the piezoelectric film 6 toward the support substrate 2.

In an acoustic wave device according to the related art, a wave that propagates is reflected by a support substrate, and a response in a higher-order mode tends to occur. Therefore, as described above, when the acoustic wave device is used as a resonator for a band pass filter, a spurious response outside a pass band may occur.

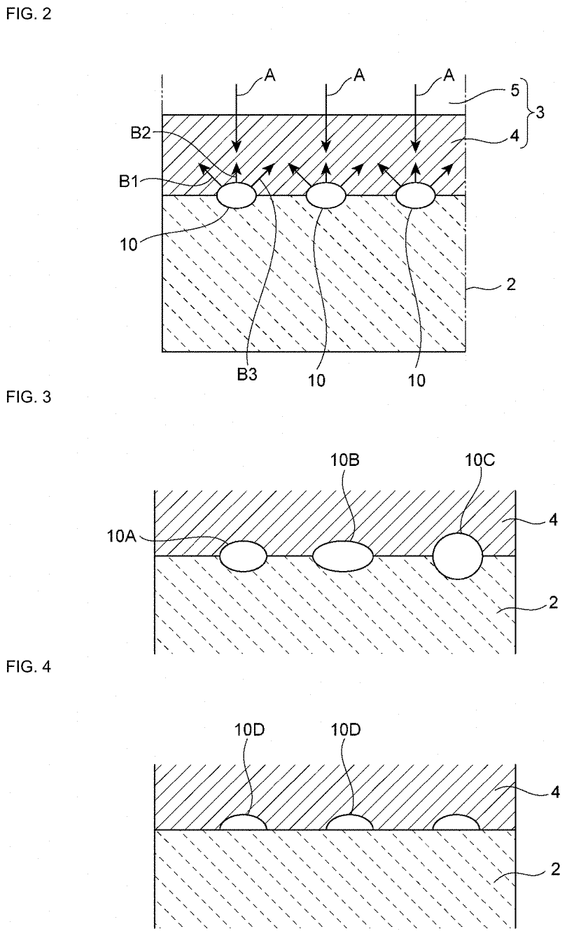

In contrast, in the acoustic wave device 1, the cavities 10 overlap the IDT electrode 7 with the intermediate layer 3 and the piezoelectric film 6 provided between the IDT electrode 7 and the cavities 10 in plan view. Therefore, portions (arrows A in FIG. 2) of the wave that propagates toward the support substrate are scattered upon reflection as shown by arrows B1 to B3. Accordingly, responses in higher-order modes may be reduced or prevented. As a result, when the acoustic wave device 1 is used as a resonator for a band pass filter, spurious responses in higher-order modes may be reduced or prevented. Thus, a band pass filter having good filter characteristics, such as attenuation frequency characteristics, may be provided.

A method for forming the cavities 10 is not particularly limited. For example, the high-acoustic-velocity film 4 may be formed after forming recesses in an upper surface of the support substrate 2 by etching or mechanical grinding.

FIG. 3 is an enlarged partial front sectional view illustrating cavities in a first modification of an acoustic wave device according to the first preferred embodiment of the present invention.

A plurality of cavities 10A to 10C have different shapes. According to a preferred embodiment of the present invention, when a plurality of cavities are provided, at least one of the cavities may have a shape that differs from that of other cavity or cavities. The cavity having a different shape may be various cavities including not only a cavity having a different cross-sectional shape but also a cavity having a different size.

In FIGS. 2 and 3, the cavities 10 and 10A to 10C extend into the support substrate 2 and the high-acoustic-velocity film 4 in partial regions between the support substrate 2 and the high-acoustic-velocity film 4.

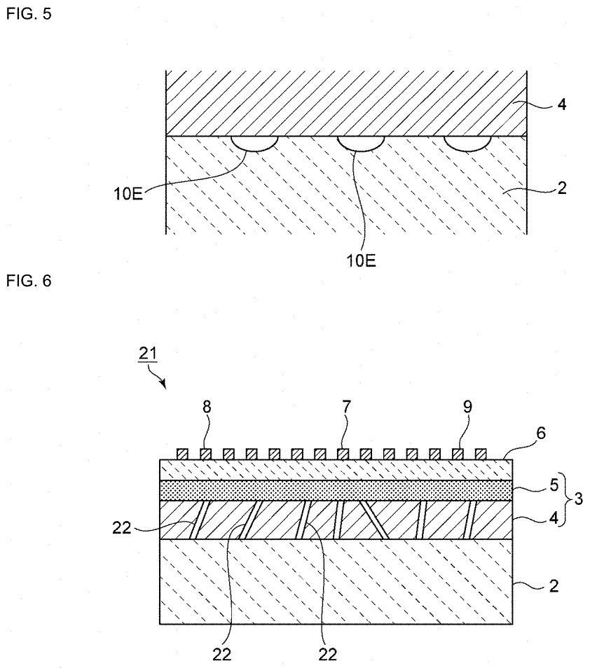

In contrast, as in a second modification illustrated in FIG. 4, cavities 10D may extend only into the high-acoustic-velocity film 4 and not into the support substrate 2 from the boundary between the support substrate 2 and the high-acoustic-velocity film 4.

Alternatively, as illustrated in FIG. 5, cavities 10E may extend only into the support substrate 2 and not into the high-acoustic-velocity film 4 from the boundary between the support substrate 2 and the high-acoustic-velocity film 4.

Thus, the cavities provided between the support substrate and the intermediate layer may be provided such that the cavities are present in partial regions between the support substrate and the intermediate layer in sectional view, and that the cavities extend into at least one of the support substrate and the intermediate layer in a lamination direction from the boundary between the support substrate and the intermediate layer.

FIG. 6 is a front sectional view of an acoustic wave device according to a second preferred embodiment of the present invention. An acoustic wave device 21 includes a plurality of cavities 22 in a high-acoustic-velocity film 4. Other structures of the acoustic wave device 21 are the same as or similar to those of the acoustic wave device 1. Therefore, the same or corresponding components are denoted by the same reference signs, and description thereof is thus omitted.

The cavities 22 in the acoustic wave device 21 are provided in an intermediate layer 3, more specifically, in the high-acoustic-velocity film 4 such that the cavities 22 extend through the high-acoustic-velocity film 4. As illustrated in FIG. 6, the cavities 22 are preferably linear and do not all extend in the same direction, and a plurality of cavities 22 that extend in different directions are provided. The directions in which the cavities 22 extend may be parallel to each other. Also when the cavities 22 are formed in the high-acoustic-velocity film 4 as described above, a wave that propagates in a lamination direction may be scattered upon reflection. Accordingly, responses in higher-order modes may be effectively suppressed.

In the acoustic wave device 21, the cavities 22 extend to both the boundary between the high-acoustic-velocity film 4 and the low-acoustic-velocity film 5 and the boundary between the high-acoustic-velocity film 4 and the support substrate 2. The cavities 22 may instead extend to only one of the boundary between the support substrate 2 and the high-acoustic-velocity film 4 and the boundary between the high-acoustic-velocity film 4 and the low-acoustic-velocity film 5. Alternatively, the cavities 22 may be positioned in the high-acoustic-velocity film 4 or in the low-acoustic-velocity film 5 such that the cavities 22 do not extend to the above-described boundaries.

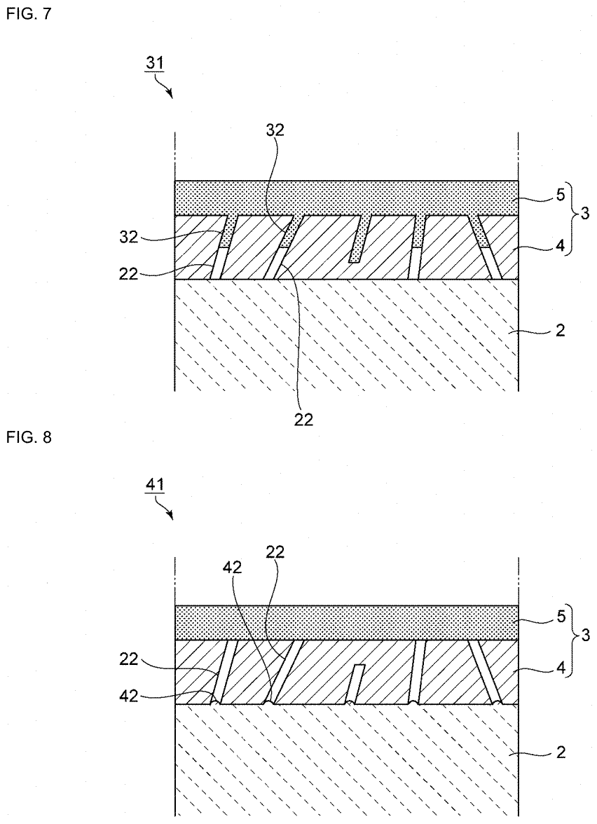

FIG. 7 is an enlarged partial front sectional view illustrating a main portion of an acoustic wave device according to a third preferred embodiment of the present invention. An acoustic wave device 31 has a plurality of cavities 22 in a high-acoustic-velocity film 4. The cavities 22 preferably include cavities that extend to both a boundary between the high-acoustic-velocity film 4 and a low-acoustic-velocity film 5 and a boundary between the high-acoustic-velocity film 4 and a support substrate 2, and a cavity that extends only to the boundary between the high-acoustic-velocity film 4 and the low-acoustic-velocity film 5.

The cavities 22 are preferably partially filled with a filler 32. More specifically, among the cavities 22, the cavities that extend to the boundary between the high-acoustic-velocity film 4 and the low-acoustic-velocity film 5 and the boundary between the high-acoustic-velocity film 4 and the support substrate 2 are partially filled with the filler 32, and the cavity that extends only to the boundary between the high-acoustic-velocity film 4 and the low-acoustic-velocity film 5 is entirely filled with the filler 32. In the present preferred embodiment, the filler 32 is preferably formed by causing portions of the low-acoustic-velocity film 5 to enter the cavities 22 when the low-acoustic-velocity film 5 is formed. The filler 32 may instead be made of a material other than the material of the low-acoustic-velocity film 5.

Thus, in a preferred embodiment of the present invention, the cavities 22 may be partially or entirely filled with a filler. Also in such a case, a wave that propagates may be scattered upon reflection, and responses in higher-order modes may be reduced or prevented.

FIG. 8 is an enlarged partial front sectional view illustrating a main portion of an acoustic wave device according to a fourth preferred embodiment of the present invention. An acoustic wave device 41 includes cavities 22 in a high-acoustic-velocity film 4. The cavities 22 include cavities that extend to both a boundary between the high-acoustic-velocity film 4 and a low-acoustic-velocity film 5 and a boundary between a support substrate 2 and the high-acoustic-velocity film 4, and a cavity that extends only to the boundary between the support substrate 2 and the high-acoustic-velocity film 4.

In the acoustic wave device 41, a filler 42 extends into the cavities 22. The filler 42 extends into the cavities 22 from the boundary between the support substrate 2 and the high-acoustic-velocity film 4. The filler 42 is preferably formed by causing the material of the support substrate 2 to enter the cavities 22. Thus, the filler 42 with which the cavities 22 are at least partially filled may be made of the material of the support substrate 2. Also in this case, since the cavities 22 are provided, a wave that propagates may be scattered upon reflection. Accordingly, responses in higher-order modes may be suppressed.

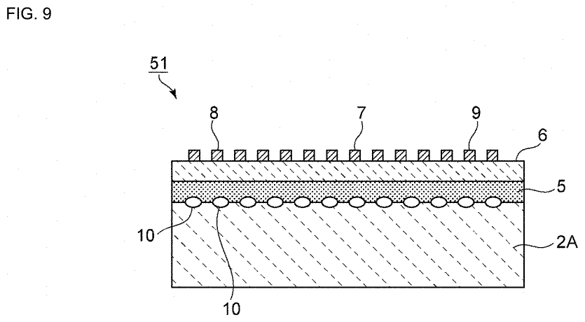

FIG. 9 is a front sectional view of an acoustic wave device according to a fifth preferred embodiment of the present invention. An acoustic wave device 51 includes a support substrate 2A that defines and functions as a high-acoustic-velocity support substrate made of a high-acoustic-velocity material. No high-acoustic-velocity film 4 is provided, and a low-acoustic-velocity film 5 is laminated directly on the support substrate 2A. Cavities 10 are provided in partial regions between the low-acoustic-velocity film 5, which defines and functions as an intermediate layer, and the support substrate 2A.

In the acoustic wave device 51, a main mode that is used is effectively confined in the piezoelectric film 6. Since the cavities 10 are provided, higher-order modes may be reduced or prevented. Therefore, also when the acoustic wave device 51 is used as a resonator of a band pass filter, spurious responses outside a pass band may be reduced or prevented.

In a preferred embodiment of the present invention, when a support substrate made of a high-acoustic-velocity material is used as in the acoustic wave device 51, the intermediate layer may be composed only of a low-acoustic-velocity film.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support substrate;
an intermediate layer on the support substrate;
a piezoelectric film on the intermediate layer; and
an interdigital transducer (IDT) electrode on the piezoelectric film; wherein
a plurality of cavities are provided at at least one of a location between the support substrate and the intermediate layer and a location in the intermediate layer; and
the plurality of cavities are positioned to overlap the IDT electrode in plan view.

2. The acoustic wave device according to claim 1, wherein the plurality of cavities include cavities having different shapes.

3. The acoustic wave device according to claim 1, wherein the plurality of cavities are provided between the support substrate and the intermediate layer.

4. The acoustic wave device according to claim 1, wherein the plurality of cavities are provided in the intermediate layer.

5. The acoustic wave device according to claim 1, wherein the intermediate layer includes a high-acoustic-velocity film and a low-acoustic-velocity film, the high-acoustic-velocity film being made of a high-acoustic-velocity material through which a bulk wave propagates at an acoustic velocity higher than an acoustic velocity at which an acoustic wave propagates through the piezoelectric film, the low-acoustic-velocity film being provided between the high-acoustic-velocity film and the piezoelectric film and made of a low-acoustic-velocity material through which a bulk wave propagates at an acoustic velocity lower than an acoustic velocity at which a bulk wave propagates through the piezoelectric film.

6. The acoustic wave device according to claim 1, wherein the intermediate layer is a low-acoustic-velocity film made of a low-acoustic-velocity material through which a bulk wave propagates at an acoustic velocity lower than an acoustic velocity at which a bulk wave propagates through the piezoelectric film, and the support substrate is a high-acoustic-velocity support substrate made of a high-acoustic-velocity material through which a bulk wave propagates at an acoustic velocity higher than an acoustic velocity at which an acoustic wave propagates through the piezoelectric film.

7. The acoustic wave device according to claim 5, wherein the plurality of cavities are provided in the high-acoustic-velocity film.

8. The acoustic wave device according to claim 5, wherein the plurality of cavities extend to at least one of a boundary between the low-acoustic-velocity film and the high-acoustic-velocity film and a boundary between the high-acoustic-velocity film and the support substrate.

9. The acoustic wave device according to claim 8, wherein among the boundary between the low-acoustic-velocity film and the high-acoustic-velocity film and the boundary between the high-acoustic-velocity film and the support substrate, the plurality of cavities extend only to the boundary between the low-acoustic-velocity film and the high-acoustic-velocity film.

10. The acoustic wave device according to claim 9, further comprising a filler with which the plurality of cavities are at least partially filled.

11. The acoustic wave device according to claim 8, wherein the plurality of cavities extend to the boundary between the low-acoustic-velocity film and the high-acoustic-velocity film and the boundary between the high-acoustic-velocity film and the support substrate.

12. The acoustic wave device according to claim 11, further comprising a filler with which the plurality of cavities are at least partially filled.

13. The acoustic wave device according to claim 10, wherein portions of the low-acoustic-velocity film extend into the plurality of cavities to define and function as the filler.

14. The acoustic wave device according to claim 1, further comprising reflectors provided on two sides of the IDT electrode in a direction in which an acoustic wave propagates.

15. The acoustic wave device according to claim 14, wherein the reflectors and the IDT electrode are defined by a multilayer body including metal films.

16. The acoustic wave device according to claim 1, wherein both of the intermediate layer and the piezoelectric film are provided between the IDT electrode and the cavities in the plan view.

17. The acoustic wave device according to claim 1, wherein the plurality of cavities include cavities having different sizes.

18. The acoustic wave device according to claim 7, wherein no portion of the plurality of cavities is provided in the low-acoustic-velocity film.

19. The acoustic wave device according to claim 7, wherein the plurality of cavities are linear and extend in different directions.

20. The acoustic wave device according to claim 7, wherein the plurality of cavities are linear and at least some of the cavities extend in directions which are parallel.
